(19) United States
(12) Patent Application Publication
(10) Pub. No.: US 2026/0214882 A1
(43) Pub. Date: Jul. 23, 2026

(54) Memory Circuitry And Methods Used In Forming Memory Circuitry

(71) Applicant: Micron Technology, Inc., Boise, ID (US)

(72) Inventors: Yuanzhi Ma, Meridian, ID (US); Ruijing Ge, Boise, ID (US); Sandeep Krishna Thirumala, Meridian, ID (US)

(73) Assignee: Micron Technology, Inc., Boise, ID (US)

(21) Appl. No.: 19/072,206

(22) Filed: Mar. 6, 2025

Related U.S. Application Data
(60) Provisional application No. 63/747,147, filed on Jan. 20, 2025.

(51) Int. Cl. H10B 12/00

(52) U.S. Cl. CPC H10B 12/30; H10B 12/02

(57) ABSTRACT

Memory circuitry comprises vertically-alternating insulative tiers and memory-cell tiers. The insulative tiers comprise insulative material that is vertically between immediately-vertically-adjacent of the memory-cell tiers. A portion of the insulative material is laterally beyond digitline-side edges of access lines vertically between insulator material that is in the immediately-vertically-adjacent memory-cell tiers between immediately-x-direction-adjacent digitlines. In such circuitry, (b) is being less than (a), where (a): minimum horizontal distance between the gate insulator of immediately-horizontally-x-direction-adjacent horizontal transistors and (b): minimum vertical thickness of the insulator material where vertically between the portions of the insulative material of immediately-vertically adjacent insulative tiers. Methods are disclosed.

### TECHNICAL FIELD

Embodiments disclosed herein pertain to memory circuitry and to methods used in forming memory circuitry.

### BACKGROUND

Memory is one type of integrated circuitry and is used in computer systems for storing data. Memory may be fabricated in one or more arrays of individual memory cells. Memory cells may be written to, or read from, using digitlines (which may also be referred to as bitlines, data lines, or sense lines) and access lines (which may also be referred to as wordlines). The sense lines may conductively interconnect memory cells along columns of the array, and the access lines may conductively interconnect memory cells along rows of the array. Each memory cell may be uniquely addressed through the combination of a sense line and an access line.

Memory cells may be volatile, semi-volatile, or non-volatile. Non-volatile memory cells can store data for extended periods of time in the absence of power. Non-volatile memory is conventionally specified to be memory having a retention time of at least about 10 years. Volatile memory dissipates and is therefore refreshed/rewritten to maintain data storage. Volatile memory may have a retention time of milliseconds or less. Regardless, memory cells are configured to retain or store memory in at least two different selectable states. In a binary system, the states are considered as either a “0” or a “1”. In other systems, at least some individual memory cells may be configured to store more than two levels or states of information.

Memory cells may be arranged or arrayed in several manners including, for example, in a vertical stack (e.g., along a vertical z direction) comprising a three-dimensional (3D) memory array region having horizontal tiers in which individual memory cells are received (e.g., arrayed in horizontal x and y directions). The stack in the 3D memory array region comprises vertically-alternating insulative tiers and conductive tiers (e.g., as part of memory-cell tiers) that extend into a stair-step region. The stair-step region includes individual “stairs” (alternately termed “steps” or “stair-steps”) that define contact regions of conductive lines of individual of the conductive tiers to which vertical conductive vias can contact to provide electrical access to/from those conductive lines.

### BRIEF DESCRIPTION OF THE DRAWINGS

FIG. 1 is a diagrammatic schematic of a DRAM memory array and peripheral circuitry in accordance with the prior art and in accordance with an embodiment of the invention.

FIG. 2 is an enlargement of a portion of FIG. 1.

FIGS. 3-9 are diagrammatic sectional views of constructions in accordance with embodiments of the invention.

FIGS. 10-19 are diagrammatic sequential sectional and/or enlarged views of the construction of FIGS. 3-9, or portions thereof or alternate and/or additional embodiments, in process in accordance with some embodiments of the invention.

### DETAILED DESCRIPTION OF EXAMPLE EMBODIMENTS

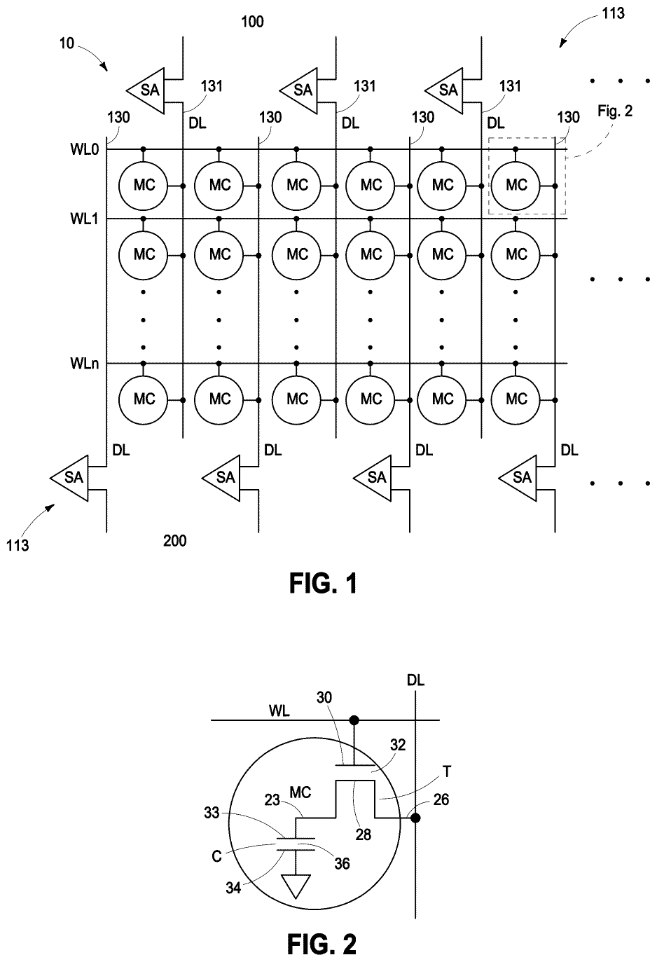

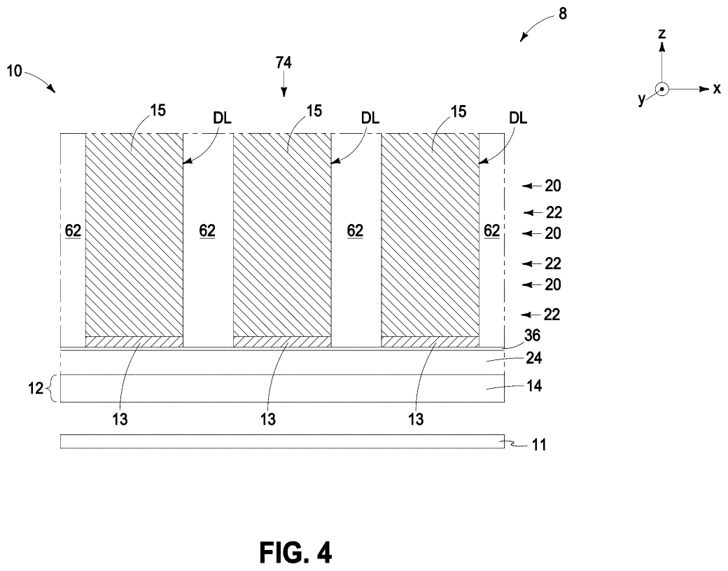

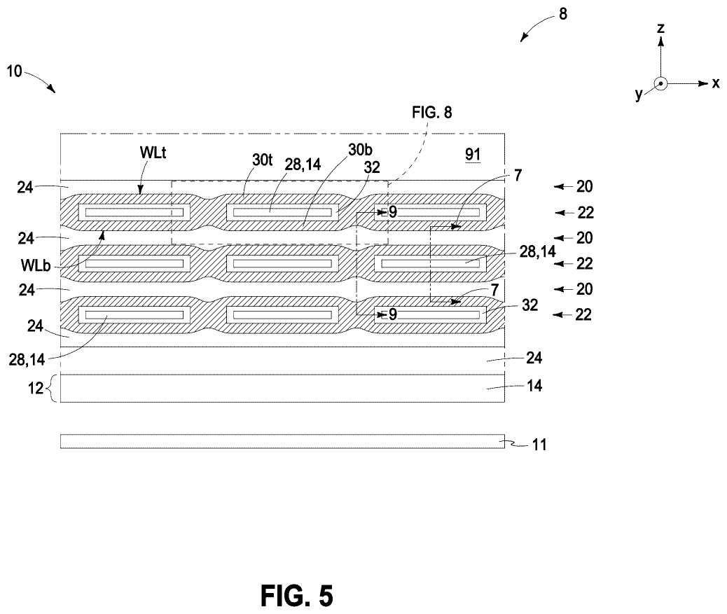

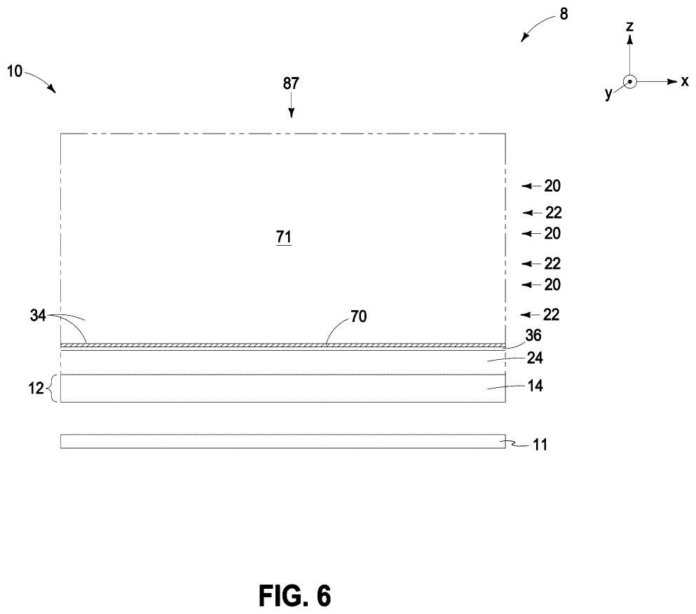

Embodiments of the invention encompass memory circuitry (e.g., DRAM) comprising vertically-stacked memory cells individually comprising a horizontal transistor and a capacitor electrically coupled therewith. Embodiments of the invention also encompass methods used in forming such memory circuitry. Example structure embodiments are first described with reference to FIGS. 1-9.

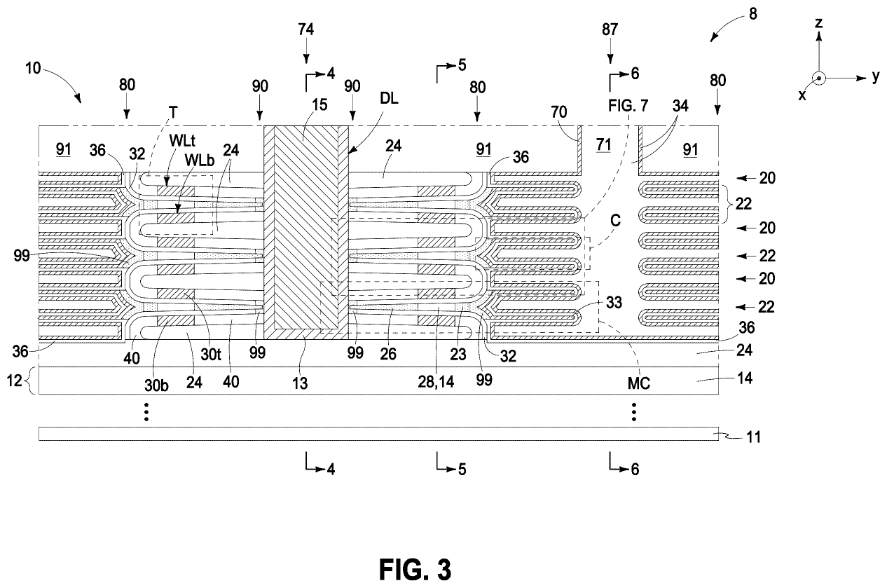

One example prior art schematic diagram of DRAM circuitry, and in accordance with an embodiment of the invention, is shown in FIGS. 1 and 2. FIG. 2 shows example memory cells MC individually comprising a transistor T and a capacitor C. One electrode of capacitor C is directly electrically coupled to a suitable potential (e.g., ground) and the other capacitor electrode is contacted with or comprises one of the source/drain regions of transistor T. The other source/drain region of transistor T is directly electrically coupled with a digitline/sense line 130 or 131 (also individually designated as DL). The gate of transistor T is directly electrically coupled with (e.g., comprises part thereof) a wordline/access line WL. FIG. 1 shows digitlines 130 and 131 extending from one of opposite sides 100 and 200 of a memory array area 10 into a peripheral circuitry area 113 that is aside memory array area 10. Digitlines 130 and 131 individually directly electrically couple with a sense amp SA on opposite sides 100 and 200 of array area 10 within peripheral circuitry area 113. Sense amps SA could be on only one side or all directly above or directly below memory array area 10. Non-schematic structure embodiments as shown herein in FIGS. 3+ have the wordlines/access lines running horizontally and the digitlines/sense lines running vertically.

Referring to FIGS. 3-9, an example fragment of a substrate construction 8 comprising array or array area 10 has been fabricated relative to a base substrate 11. Substrate 11 may comprise any one or more of conductive/conductor/conducting, semiconductive/semiconductor/semiconducting, and insulative/insulator/insulating (i.e., electrically herein) materials. Materials may be aside, elevationally inward, or elevationally outward of the FIG. 3-9-depicted materials. For example, other partially or wholly fabricated components of integrated circuitry may be provided somewhere above, about, or within base substrate 11. Control and/or other peripheral circuitry for operating components within a memory array may also be fabricated and may or may not be wholly or partially within a memory array or sub-array. Further, multiple sub-arrays may also be fabricated and operated independently, in tandem, or otherwise relative one another. As used in this document, a “sub-array” may also be considered as an array. Example construction 8 comprises a semiconductor substrate 12 (e.g., monocrystalline silicon 14) having insulative material 24 there-above (e.g., silicon dioxide and/or silicon nitride).

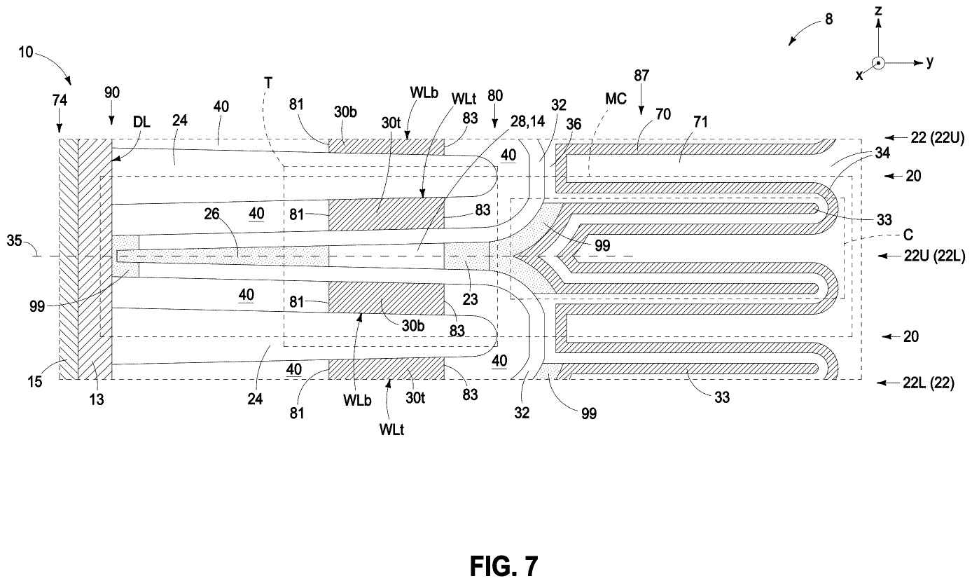

Example memory circuitry (e.g., that of or comprising construction 8) comprises vertically-alternating insulative tiers 20 and memory-cell tiers 22* (e.g., along example direction z; an * being used as a suffix to be inclusive of all such same-numerically-designated structures or portions thereof that may or may not have other suffixes). Insulative tiers 20 comprise insulative material 24 that is vertically between immediately-vertically-adjacent memory-cell tiers 22*. An example insulating material/hardmask 91 (e.g., silicon dioxide) is above tiers 20 and 22. Memory cells MC are in memory-cell tiers 22* and individually comprise a horizontal transistor T and a capacitor C. Horizontal transistor T has a gate 30*, a capacitor side 80, and a digitline side 90. A horizontally-elongated trench 74 is shown in construction 8 on digitline side 90 (e.g., a digitline trench). A horizontally-elongated trench 87 is shown in construction 8 on capacitor side 80 (e.g., a capacitor trench). Capacitor C is electrically coupled (e.g., directly electrically coupled) with horizontal transistor T on capacitor side 80. A digitline DL is electrically coupled (e.g., directly electrically coupled) with horizontal transistor T on digitline side 90. Immediately-vertically-adjacent of the memory-cell tiers comprise an upper memory-cell tier (e.g., 22U in FIG. 7) and a lower memory-cell tier (e.g., 22L in FIG. 7) (there being no other such noun [tier] between those that are immediately-adjacent one another). Each memory-cell tier 22* may of course be considered as either an upper or a lower memory-cell tier depending on whether “immediately-vertically-adjacent” is referring to above or below with respect to the tiers 22* at issue.

Example horizontal transistor T comprises a first source/drain region 23 (e.g., conductively-doped silicon), a second source/drain region 26 (e.g., conductively-doped silicon), and a channel region 28 (e.g., lightly-doped or undoped silicon 14) horizontally between the first and second source/drain regions. The y-direction lengths of regions 23, 26, and 28 are diagrammatic in the figures. Such may be of equal or different lengths relative one another than is shown. Regions 23 and 26 of different immediately-horizontally-adjacent memory cells MC running into and out of the plane of the page upon which FIG. 3 lies in a common memory-cell tier 22* (along a horizontal x-direction) may be isolated relative one another by insulative material (not shown). A horizontal axis 35 (FIG. 7) extends from capacitor side 80 to digitline side 90 through channel region 28 and source/drain regions 23, 26 along a horizontal y-direction (that is perpendicular the x-direction). In some embodiments, regions 23, 26, and/or 28 taper towards digitline DL.

Example gate 30* (e.g., conductive metal material) of transistor T is gate-all-around channel region 28 having a gate insulator 32 (e.g., dielectric or ferroelectric) between at least channel region 28 and gate 30*. Gate 30* comprises part of a one of a plurality of horizontal conductive access lines WL* that individually directly electrically couple together multiple gates 30* of different ones of horizontal transistors T that are in the same memory-cell tier 22*. Access lines WL* are horizontally elongated in the x-direction and are spaced relative one another in the y-direction. An example insulator material 40 (e.g., silicon nitride) is laterally proximate lateral sides/edges of gates 30* (e.g., digitline-side edge 81 and capacitor-side edge 83). In one embodiment and as shown, gate 30* comprises a top gate 30t that is part of a top conductive access line WLt and comprises a bottom gate 30b that is part of a bottom conductive access line WLb. In one embodiment and as shown, gate insulator 32 extends laterally beyond digitline-side edge 81. The y-direction lengths of conductive access lines WLt and WLb are diagrammatic. Such may be of equal or different lengths relative one another than is shown and/or may or may not be centered in the y-direction (with channel region 28) between the capacitors and transistors.

Example capacitor C comprises a storage-node electrode 33, a common electrode 34 (e.g., comprising conductive metal material 70 and conductively-doped polysilicon 71) that is common (directly electrically coupled) to a plurality of capacitors C (at least some, not necessarily all) of memory cells MC, and a capacitor insulator 36 there-between (e.g., dielectric or ferroelectric). Storage-node electrode 33 is directly coupled to first source/drain region 23 of transistor T. Conductively-doped semiconductive material 99 (e.g., conductively-doped epitaxial silicon) may be between storage-node electrode 33 and first source/drain region 23 (e.g., and such may be considered as a part of either or both).

Digitlines DL (e.g., comprising conductive materials 13 and 15) extend through vertically-alternating tiers 20 and 22*. Conductively-doped semiconductive material 99 may be between/proximate digitline DL and second source/drain region 26. Digitlines DL of different immediately-horizontally-adjacent memory cells MC running into and out of the plane of the page upon which FIG. 3 lies (in the x-direction) may be isolated relative one another by insulative material 62 (e.g., silicon dioxide and/or silicon nitride). Individual second source/drain regions 26 of individual transistors T that are in different memory-cell tiers 22* are electrically coupled (e.g., directly electrically coupled) to individual digitlines DL. Capacitor C and horizontal transistor T may be considered as being horizontally spaced relative one another along horizontal axis 35 (FIG. 7) along the y-direction.

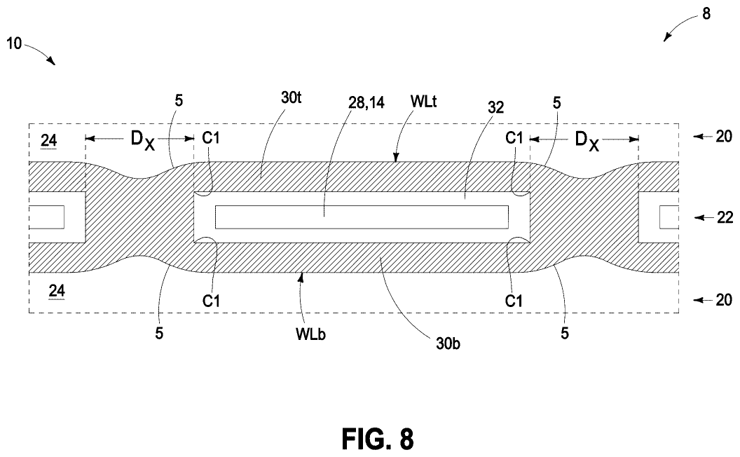

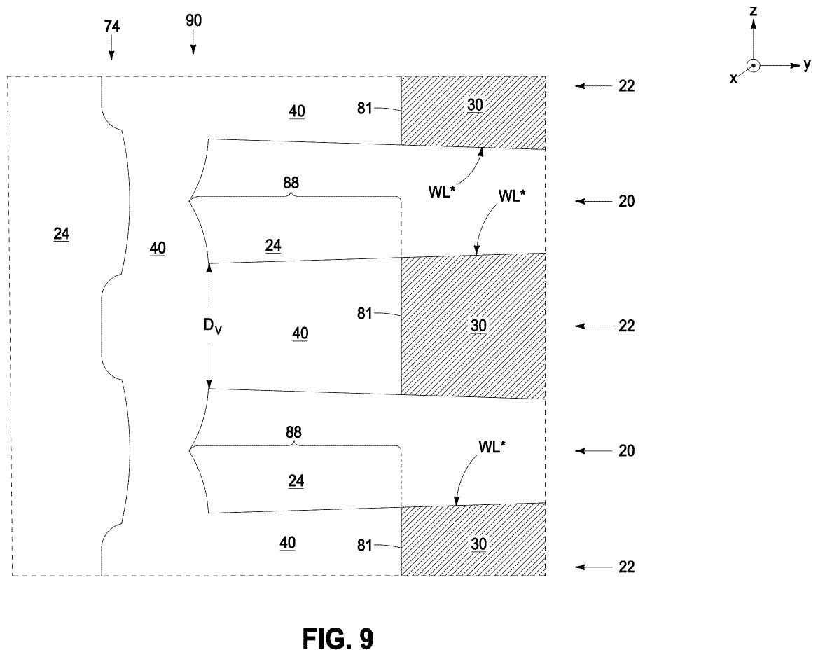

Insulator material 40 is on a digitline-side edge 81 of individual access lines WL* between immediately-adjacent digitlines DL in the x-direction (FIG. 9). That insulator material 40 there-between tapers away from such digitline-side edge 81. A portion 88 of insulative material 24 is laterally beyond such digitline-side edge 81 vertically between that part of insulator material 40 that is in immediately-vertically-adjacent memory-cell tiers MC between immediately-x-direction-adjacent digitlines DL (e.g., FIG. 9 being such a latter location). In such, (b) is less than (a), where:
(a): minimum horizontal distance Dₓ (FIG. 8) between gate insulator 32 of immediately-horizontally-adjacent horizontal transistors T along the x-direction; and
(b): minimum vertical thickness Dᵥ (FIG. 9) of insulator material 40 where vertically between portions 88 of insulative material 24 of immediately-vertically adjacent insulative tiers 20.
   In some embodiments and as shown, portions 88 of insulative material 24 taper along the y-direction towards capacitor C and/or access lines WL* between immediately-adjacent digitlines DL taper along the y-direction towards digitlines DL. In one embodiment where both, and as shown each, of portions 88 of insulative material 24 and access lines WL* tapers in the same degree (e.g., that may be constant or variable).

In one embodiment, insulator material 40 extends vertically along vertically-alternating insulative tiers 20 and memory-cell tiers 22* between digitlines DL that are immediately-adjacent one another in the x-direction (FIG. 9). In some embodiments and as shown, channel region 28, 14 of horizontal transistor T and/or a source/drain region (one of 23 or 26, or both) taper(s) towards digitline DL.

Any other attribute(s) or aspect(s) as shown and/or described herein with respect to other embodiments may be used in the embodiments shown and described with reference to the above embodiments.

Embodiments of the invention encompass methods used in forming memory circuitry, by way of example only that incorporates device/structure as referred to above. Nevertheless, the method embodiments may incorporate, form, and/or have any of the attributes described with respect to device embodiments.

FIGS. 10-19 by way of example sequentially show predecessor constructions in an example method used in forming memory circuitry in accordance with embodiments of the invention. Such memory circuitry ultimately comprises vertically-stacked memory cells individually comprising a horizontal transistor and a capacitor electrically coupled (e.g., directly) therewith. Such memory circuitry may comprise structural embodiments of the invention as described above with respect to FIGS. 3-9.

Referring to FIGS. 10 and 11, vertically-alternating insulative tiers 20 and memory-cell tiers 22* have been formed. Such as shown in the far-right portion of FIG. 10 comprises an initial vertical stack comprising alternating layers of semiconductor material 14 and a much thinner material 68 that can be etched at least somewhat selectively relative to material 14 (e.g., a silicon-germanium alloy). Memory cells (not-yet-formed) of memory-cell tiers 22* individually comprise a horizontal transistor (not-yet-completely-formed) and a capacitor (not-yet-formed) in a finished memory-circuitry construction. The horizontal transistor in the finished circuitry construction has a gate 30* (not-yet-formed), a capacitor side 80, and a digitline side 90. Example memory-cell tiers 22* comprise doped or undoped semiconductor material 14 which may in its intrinsic composition be used as a channel material/region 14, 28. Such is shown as being lightly stippled for clarity in FIGS. 10-17, although corresponding channel material/region 14, 28 is not shown as being stippled in FIGS. 3-9, 18, and 19. In one ideal embodiment, insulating material (e.g., 40) is formed in memory-cell tiers 22* to leave void-space 75 in insulative tiers 20 vertically between immediately-vertically adjacent memory-cell tiers 22*. Such insulating material may be of the same or different composition as insulator material 40 that will be on digitline-side edge 81, with same composition intended to be shown/designated with numeral 40 for such insulating material.

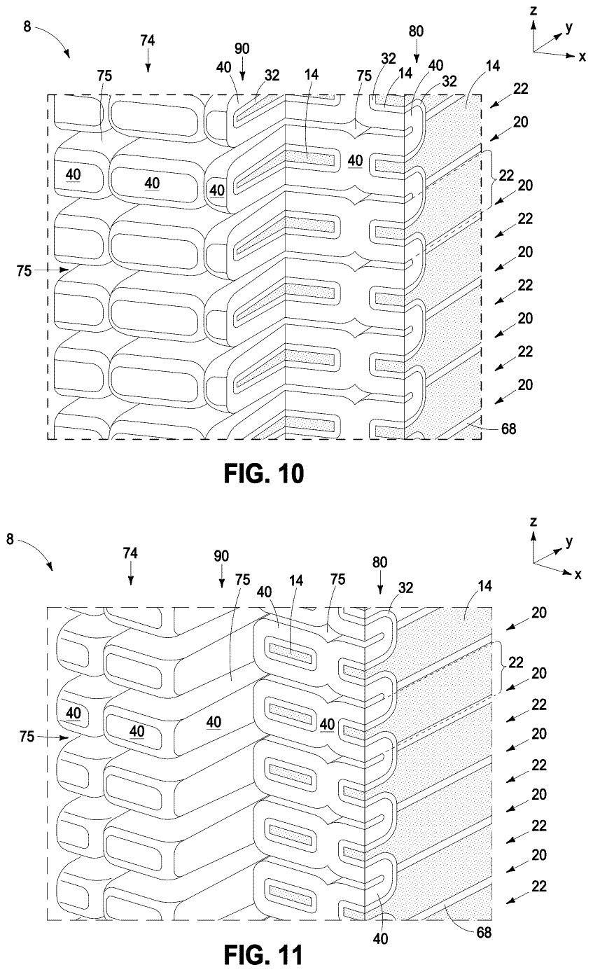

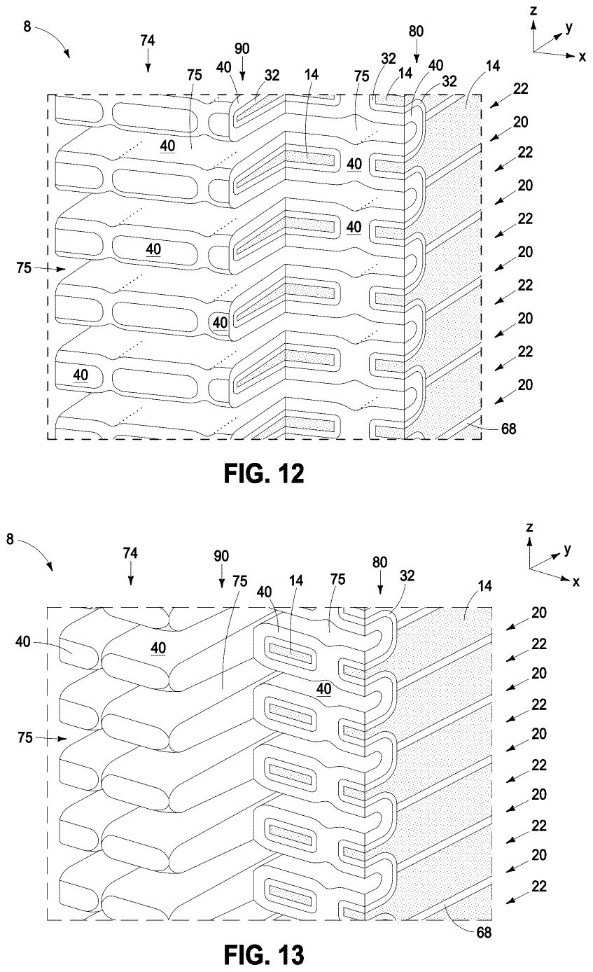

Referring to FIGS. 12 and 13, some of insulating material 40 has been removed (e.g., by etching) to vertically widen void-space 75. As an example, where insulating material 40 is silicon nitride, a phosphoric acid solution may be used for such removing to form the depicted construction.

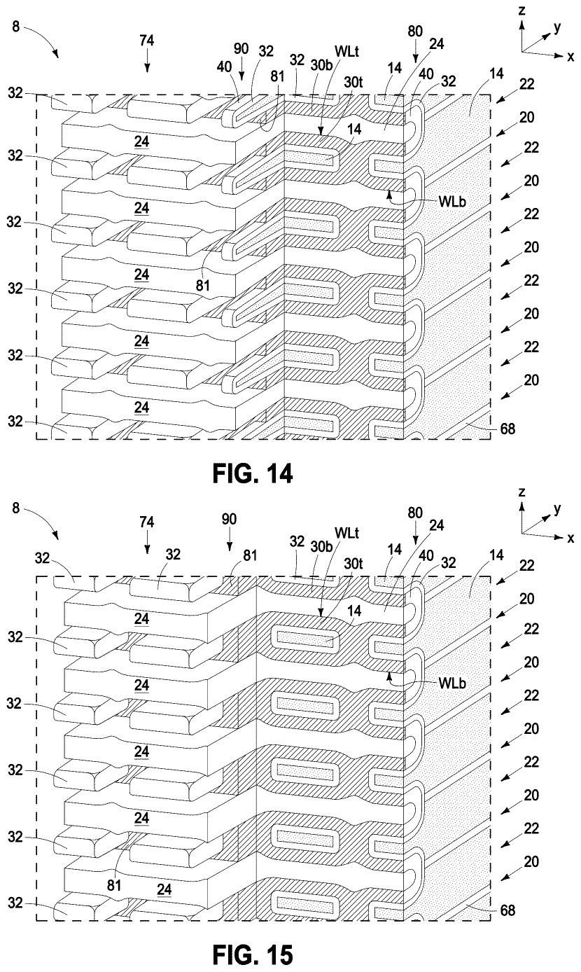

Referring to FIGS. 14 and 15, several processing steps have occurred. Insulative material 24 of insulative tiers 20 was formed in widened void-spaces 75. Such was then etched back in digitline trenches 74 to expose insulating material 40 therein (such insulating material 40 in trench 74 not being visible). Such insulating material 40 was then etched back to have an edge positionally corresponding to capacitor-side edge 83 (FIG. 7). Conductive material of access lines WL* was then formed and etched back as shown whereby gates 30* and access lines WL* are formed.

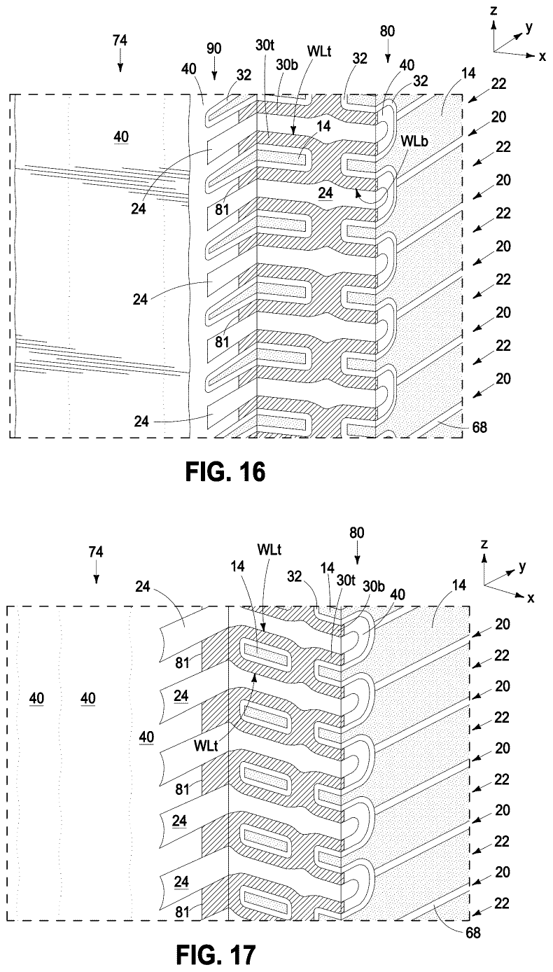

Referring to FIGS. 16 and 17, insulator material 40 has been formed on digitline-side edge 81 of individual access lines WL* in the location that is between what will be immediately-adjacent digitlines DL in the x-direction in the finished-circuitry construction (e.g., the z-y portion of the cut as shown in FIG. 17 being such a location). Insulator material 40 tapers away from digitline-side edge 81 (e.g., becomes progressively thinner towards the vertical plane where the digitlines will be formed; e.g., see insulator material 40 in FIG. 9).

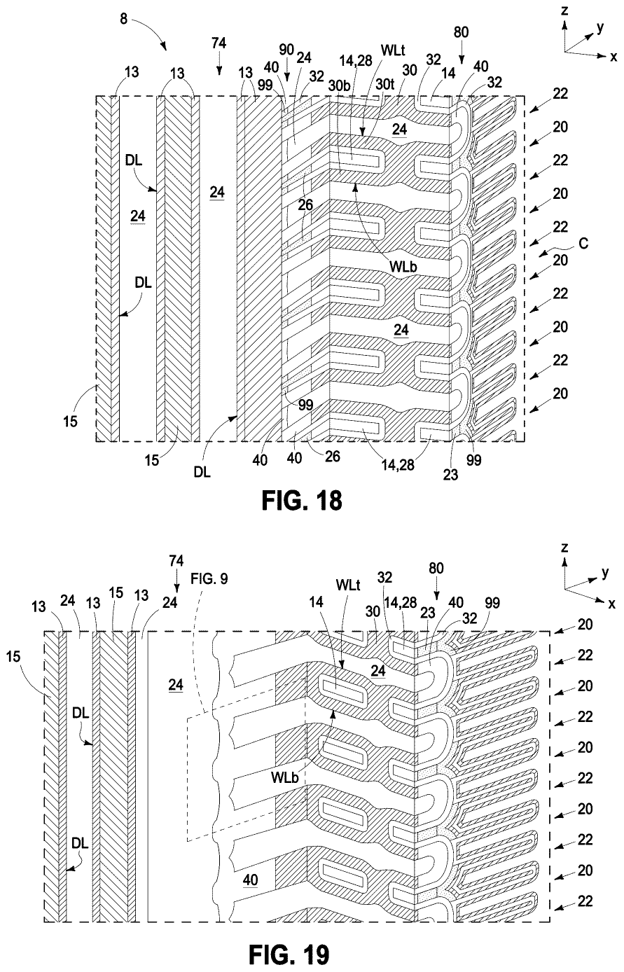

Referring to FIGS. 18 and 19, several processing steps have occurred. Some of insulator material 40 was removed from digitline trenches 74 to expose semiconductor material 14 of memory-cell tiers 22*. Such exposed material 14 was then conductively doped to form source/drain region 26 (e.g., by gas-phase diffusion). Conductively-doped epitaxial silicon 99 was then grown from exposed semiconductor material 14 (source/drain region 26 thereof). Digitlines DL and insulative material 24 were then formed in digitline trenches 74.

Insulative material 24 may be considered as having a portion 88 that is laterally beyond digitline-side edge 81 vertically between insulator material 40 that is in the immediately-vertically-adjacent memory-cell tiers 22* between immediately-x-direction-adjacent digitlines DL (FIGS. 9 and 19). In such, (b) is less than (a), where:
(a): minimum horizontal distance Dₓ (FIG. 8) between gate insulator 32 of immediately-horizontally-adjacent horizontal transistors T along the x-direction; and
(b): minimum vertical thickness Dᵥ (FIG. 9) of insulator material 40 where vertically between portions 88 of insulative material 24 of immediately-vertically adjacent insulative tiers 20.

Any other attribute(s) or aspect(s) as shown and/or described herein with respect to other embodiments may be used.

Some embodiments of the invention were motivated towards reducing existence or volume of void-spaces in the conductive material of access lines WL* that can develop between the gate insulator of immediately-horizontally-adjacent horizontal transistors in the x-direction. Embodiments herein may reduce the existence or volume of such void-spaces (e.g., (b) being less than (a) may preclude formation of such void-spaces). For example, in method and by way of example only, forming insulator material 40 to an initial thickness (e.g., FIGS. 10 and 11) and then thinning it by wet etching (e.g., FIGS. 12 and 13) can better result in (b) being less than (a) compared to attempting to form insulator material 40 initially to its final thickness (FIGS. 12 and 13). As vertical thickness of access lines WL* is determined by vertical thickness of insulator material 40 that such replaces, processing as just described may facilitate reduction or elimination of such void-spaces.

Further, in prior constructions having top and bottom access lines, an outer surface arc of each between immediately-x-direction-adjacent channel regions would be centered on the point defined by the respective closest corner of the gate insulator (e.g., point C1 in FIG. 8; e.g., which would likely be rounded and not shown). This would tend towards shortening a minimum vertical thickness of the access lines between immediately-x-direction-adjacent channel regions (e.g., as a result of creating deep vertically opposing dimples). Such would also tend towards such undesired void-space formation in these minimum-vertical-thickness regions. Method embodiments of the invention, and by way of example only, may increase the radius of such arcs (e.g., arcs 5 in FIG. 8) and move their center points (not shown) away from that corner.

The above processing(s) or construction(s) may be considered as being relative to an array of components formed as or within a single stack or single deck of such components above or as part of an underlying base substrate (albeit, the single stack/deck may have multiple tiers). Control and/or other peripheral circuitry for operating or accessing such components within an array may also be formed anywhere as part of the finished construction, and in some embodiments may be under the array (e.g., CMOS under-array). Regardless, one or more additional such stack(s)/deck(s) may be provided or fabricated above and/or below that shown in the figures or described above. Further, the array(s) of components may be the same or different relative one another in different stacks/decks and different stacks/decks may be of the same thickness or of different thicknesses relative one another. Intervening structure may be provided between immediately-vertically-adjacent stacks/decks (e.g., additional circuitry and/or dielectric layers). Also, different stacks/decks may be electrically coupled relative one another. The multiple stacks/decks may be fabricated separately and sequentially (e.g., one atop another), or two or more stacks/decks may be fabricated at essentially the same time.

The circuitry described herein (e.g., conductive vias thereof) may connect with circuitry that is on either the top or the bottom (i.e., either z-axis side) of the vertical stack regardless of orientation of the construction in three-dimensional space and which is not material to aspects of the inventions disclosed herein. For example, and by way of example only, conductive vias may connect with peripheral control circuitry that is beneath the stack with respect to the orientation shown in the drawings. As an alternate example, and by way of example only, conductive vias may connect with peripheral control circuitry that is above the stack with respect to the shown orientation, for example to another substrate having such circuitry and that is bonded with the top of the stack with respect to the shown orientation. In such alternate example, the construction may be inverted from the shown orientation and then bonded with the other substrate. Further, in such alternate example, electronic components may be fabricated relative to the bottom of the stack with respect to the shown orientation but inverted therefrom during processing. Such electronic components may connect with conductive vias that extend through the stack to the substrate bonded with the other side that has such peripheral control circuitry. Regardless, constructions as shown and described herein may be processed, packaged, and/or mounted in any three-dimensional spatial orientation.

The assemblies and structures discussed above may be used in integrated circuits/circuitry and may be incorporated into electronic systems. Such electronic systems may be used in, for example, memory modules, device drivers, power modules, communication modems, processor modules, and application-specific modules, and may include multilayer, multichip modules. The electronic systems may be any of a broad range of systems, such as, for example, cameras, wireless devices, displays, chip sets, set top boxes, games, lighting, vehicles, clocks, televisions, cell phones, personal computers, automobiles, industrial control systems, aircraft, etc.

In this document unless otherwise indicated, “elevational”, “higher”, “upper”, “lower”, “top”, “atop”, “bottom”, “above”, “below”, “under”, “beneath”, “up”, and “down” are generally with reference to the vertical direction. “Horizontal” refers to a general direction (i.e., within 10 degrees) along a primary substrate surface and may be relative to which the substrate is processed during fabrication, and vertical is a direction generally orthogonal thereto. Reference to “exactly horizontal” is the direction along the primary substrate surface (i.e., no degrees there-from) and may be relative to which the substrate is processed during fabrication and as shown in drawings (if any) herein. Further, “vertical” and “horizontal” as used herein are generally perpendicular directions relative one another and independent of orientation of the substrate in three-dimensional space during fabrication and/or in a finished construction. Additionally, “elevationally-extending” and “extend(ing) elevationally” refer to a direction that is angled away by at least 45° from exactly horizontal. Further, “extend(ing) elevationally”, “elevationally-extending”, “extend(ing) horizontally”, “horizontally-extending” and the like with respect to a field effect transistor are with reference to orientation of the transistor's channel length along which current flows in operation between the source/drain regions. For bipolar junction transistors, “extend(ing) elevationally” “elevationally-extending”, “extend(ing) horizontally”, “horizontally-extending” and the like, are with reference to orientation of the base length along which current flows in operation between the emitter and collector. In some embodiments, any component, feature, and/or region that extends elevationally extends vertically or within 10° of vertical.

Further, “directly above”, “directly below”, and “directly under” require at least some lateral overlap (i.e., horizontally) of two stated regions/materials/components relative one another. Also, use of “above” not preceded by “directly” only requires that some portion of the stated region/material/component that is above the other be elevationally outward of the other (i.e., independent of whether there is any lateral overlap of the two stated regions/materials/components). Analogously, use of “below” and “under” not preceded by “directly” only requires that some portion of the stated region/material/component that is below/under the other be elevationally inward of the other (i.e., independent of whether there is any lateral overlap of the two stated regions/materials/components).

Any of the materials, regions, and structures described herein may be homogenous or non-homogenous, and regardless may be continuous or discontinuous over any material which such overlie. Where one or more example composition(s) is/are provided for any material, that material may comprise, consist essentially of, or consist of such one or more composition(s). Further, unless otherwise stated, each material may be formed using any suitable existing or future-developed technique, with atomic layer deposition, chemical vapor deposition, physical vapor deposition, epitaxial growth, diffusion doping, and ion implanting being examples.

Additionally, “thickness” by itself (no preceding directional adjective) is defined as the mean straight-line distance through a given material or region perpendicularly from a closest surface of an immediately-adjacent material of different composition or of an immediately-adjacent region. Additionally, the various materials or regions described herein may be of substantially constant thickness or of variable thicknesses. If of variable thickness, thickness refers to average thickness unless otherwise indicated, and such material or region will have some minimum thickness and some maximum thickness due to the thickness being variable. As used herein, “different composition” only requires those portions of two stated materials or regions that may be directly against one another to be chemically and/or physically different, for example if such materials or regions are not homogenous. If the two stated materials or regions are not directly against one another, “different composition” only requires that those portions of the two stated materials or regions that are closest to one another be chemically and/or physically different if such materials or regions are not homogenous. In this document, a material, region, or structure is “directly against” another when there is at least some physical touching contact of the stated materials, regions, or structures relative one another. In contrast, “over”, “on”, “adjacent”, “along”, and “against” not preceded by “directly” encompass “directly against” as well as construction where intervening material(s), region(s), or structure(s) result(s) in no physical touching contact of the stated materials, regions, or structures relative one another.

Herein, regions-materials-components are “electrically coupled” relative one another if in normal operation electric current is capable of continuously flowing from one to the other and does so predominately by movement of subatomic positive and/or negative charges when such are sufficiently generated. Another electronic component may be between and electrically coupled to the regions-materials-components. In contrast, when regions-materials-components are referred to as being “directly electrically coupled”, no intervening electronic component (e.g., no diode, transistor, resistor, transducer, switch, fuse, etc.) is between the directly electrically coupled regions-materials-components.

Any use of “row” and “column” in this document is for convenience in distinguishing one series or orientation of features from another series or orientation of features and along which components have been or may be formed. “Row” and “column” are used synonymously with respect to any series of regions, components, and/or features independent of function. Regardless, the rows may be straight and/or curved and/or parallel and/or not parallel relative one another, as may be the columns. Further, the rows and columns may intersect relative one another at 90° or at one or more other angles (i.e., other than the straight angle).

The composition of any of the conductive/conductor/conducting materials herein may be conductive metal material and/or conductively-doped semiconductive/semiconductor/semiconducting material. “Metal material” is any one or combination of an elemental metal, any mixture or alloy of two or more elemental metals, and any one or more metallic compound(s).

Herein, any use of “selective” as to etch, etching, removing, removal, depositing, forming, and/or formation is such an act of one stated material relative to another stated material(s) so acted upon at a rate of at least 2:1 by volume. Further, any use of selectively depositing, selectively growing, or selectively forming is depositing, growing, or forming one material relative to another stated material or materials at a rate of at least 2:1 by volume for at least the first 75 Angstroms of depositing, growing, or forming.

Unless otherwise indicated, use of “or” herein encompasses either and both.

### CONCLUSION

In some embodiments, a method used in forming memory circuitry comprises forming vertically-alternating insulative tiers and memory-cell tiers. Memory cells of the memory-cell tiers individually comprise a horizontal transistor and a capacitor in a finished-circuitry construction. The horizontal transistor in the finished-circuitry construction has a gate, a gate insulator, a capacitor side, and a digitline side. A plurality of access lines is formed that are horizontally elongated in a horizontal x-direction and spaced relative one another in a horizontal y-direction that is perpendicular the x-direction. The access lines individually directly electrically couple together multiple of the gates of different ones of the horizontal transistors that are in the same memory-cell tier. Insulator material is formed on a digitline-side edge of individual of the access lines between what will be immediately-adjacent of the digitlines in the x-direction in the finished-circuitry construction. The insulator material tapers away from the digitline-side edge. The insulative tiers are formed to comprise insulative material that is vertically between immediately-vertically-adjacent of the memory-cell tiers. A portion of the insulative material is laterally beyond a digitline-side edge vertically between the insulator material that is in the immediately-vertically-adjacent memory-cell tiers between the immediately-x-direction-adjacent digitlines. In such, (b) is less than (a), where:
(a): minimum horizontal distance between the gate insulator of immediately-horizontally-adjacent of the horizontal transistors along the x-direction; and
(b): minimum vertical thickness of the insulator material where vertically between the portions of the insulative material of immediately-vertically adjacent of the insulative tiers.

In some embodiments, memory circuitry comprises vertically-alternating insulative tiers and memory-cell tiers. Memory cells in the memory-cell tiers individually comprise a horizontal transistor having a gate, a gate insulator, a capacitor side, and a digitline side. The gate comprises part of one of a plurality of access lines that individually directly electrically couple together multiple of the gates of different ones of the horizontal transistors that are in the same memory-cell tier. The access lines are horizontally elongated in a horizontal x-direction and spaced relative one another in a horizontal y-direction that is perpendicular the x-direction. A capacitor is electrically coupled with individual of the horizontal transistors on the capacitor side. Digitlines are individually electrically coupled with the individual horizontal transistors on the digitline side. Between immediately-adjacent of the digitlines in the x-direction, the memory-cell tiers comprise insulator material on a digitline-side edge of individual of the access lines. The insulator material tapers away from the digitline-side edge. The insulative tiers comprise insulative material that is vertically between immediately-vertically-adjacent of the memory-cell tiers. A portion of the insulative material is laterally beyond the digitline-side edge vertically between the insulator material that is in the immediately-vertically-adjacent memory-cell tiers between the immediately-x-direction-adjacent digitlines. In such, (b) is less than (a), where:
(a): minimum horizontal distance between the gate insulator of immediately-horizontally-adjacent of the horizontal transistors along the x-direction; and
(b): minimum vertical thickness of the insulator material where vertically between the portions of the insulative material of immediately-vertically adjacent of the insulative tiers.

In some embodiments, memory circuitry comprises vertically-alternating insulative tiers and memory-cell tiers. Memory cells in the memory-cell tiers individually comprise a horizontal transistor having a gate, a gate insulator, a capacitor side, and a digitline side. The gate comprises part of one of a plurality of access lines that individually directly electrically couple together multiple of the gates of different ones of the horizontal transistors that are in the same memory-cell tier. The access lines are horizontally elongated in a horizontal x-direction and spaced relative one another in a horizontal y-direction that is perpendicular the x-direction. A capacitor is electrically coupled with individual of the horizontal transistors on the capacitor side. Digitlines are individually electrically coupled with the individual horizontal transistors on the digitline side. The horizontal transistor comprises a channel region that tapers towards the digitline. The horizontal transistor comprises two source/drain regions that taper towards the digitline. Between immediately-adjacent of the digitlines in the x-direction, the memory-cell tiers comprise insulator material on a digitline-side edge of individual of the access lines. The insulator material tapers away from the digitline-side edge. The insulator material extends vertically along the vertically-alternating insulative tiers and memory-cell tiers between the digitlines that are immediately-adjacent one another in the x-direction. The access lines between the immediately-adjacent digitlines taper along the y-direction towards the digitlines. The insulative tiers comprise insulative material that is vertically between immediately-vertically-adjacent of the memory-cell tiers. A portion of the insulative material is laterally beyond the digitline-side edge vertically between the insulator material that is in the immediately-vertically-adjacent memory-cell tiers between the immediately-x-direction-adjacent digitlines. The portion tapers along the y-direction towards the capacitor. In such, (b) is less than (a), where:
(a): minimum horizontal distance between the gate insulator of immediately-horizontally-adjacent of the horizontal transistors along the x-direction; and
(b): minimum vertical thickness of the insulator material where vertically between the portions of the insulative material of immediately-vertically adjacent of the insulative tiers.

In compliance with the statute, the subject matter disclosed herein has been described in language more or less specific as to structural and methodical features. It is to be understood, however, that the claims are not limited to the specific features shown and described, since the means herein disclosed comprise example embodiments. The claims are thus to be afforded full scope as literally worded, and to be appropriately interpreted in accordance with the doctrine of equivalents.

1. A method used in forming memory circuitry, comprising:
forming vertically-alternating insulative tiers and memory-cell tiers, memory cells of the memory-cell tiers individually comprising a horizontal transistor and a capacitor in a finished-circuitry construction; the horizontal transistor in the finished-circuitry construction having a gate, a gate insulator, a capacitor side, and a digitline side;
forming a plurality of access lines that are horizontally elongated in a horizontal x-direction and spaced relative one another in a horizontal y-direction that is perpendicular the x-direction, the access lines comprising and individually directly electrically coupling together multiple of the gates of different ones of the horizontal transistors that are in the same memory-cell tier;
forming insulator material on a digitline-side edge of individual of the access lines between what will be immediately-adjacent of the digitlines in the x-direction in the finished-circuitry construction, the insulator material tapering away from the digitline-side edge;
forming the insulative tiers to comprise insulative material that is vertically between immediately-vertically-adjacent of the memory-cell tiers, a portion of the insulative material being laterally beyond a digitline-side edge vertically between the insulator material that is in the immediately-vertically-adjacent memory-cell tiers between the immediately-x-direction-adjacent digitlines; and
(b) being less than (a), where:
(a): minimum horizontal distance between the gate insulator of immediately-horizontally-adjacent of the horizontal transistors along the x-direction; and
(b): minimum vertical thickness of the insulator material where vertically between the portions of the insulative material of immediately-vertically adjacent of the insulative tiers.

2. The method of claim 1 comprising forming the insulative material before forming the insulator material.

3. The method of claim 2 comprising:
forming insulating material in the memory cell tiers to leave void-space in the insulative tiers vertically between the immediately-vertically adjacent memory cell tiers;
removing some of the insulating material to vertically widen the void-space; and
after the removing, forming the insulative material in the widened-void-space.

4. The method of claim 3 wherein the insulating material and the insulator material are of the same composition relative one another.

5. The method of claim 1 wherein the portions of the insulative material taper along the y-direction towards the capacitor.

6. The method of claim 1 wherein the access lines between the immediately-adjacent digitlines taper along the y-direction towards the digitlines.

7. The method of claim 1 wherein,
the portions of the insulative material taper along the y-direction towards the capacitor; and
the access lines between the immediately-adjacent digitlines taper along the y-direction towards the digitlines.

8. The method of claim 7 wherein the tapering of each of the portions of the insulative material and the access lines taper in the same degree.

9. The method of claim 8 wherein the degree is constant.

10. The method of claim 1 wherein the insulator material extends vertically along the vertically-alternating insulative tiers and memory-cell tiers between the digitlines that are immediately-adjacent one another in the x-direction.

11. Memory circuitry comprising:
vertically-alternating insulative tiers and memory-cell tiers;
memory cells in the memory-cell tiers that individually comprise a horizontal transistor having a gate, a gate insulator, a capacitor side, and a digitline side; the gate comprising part of one of a plurality of access lines that individually directly electrically couple together multiple of the gates of different ones of the horizontal transistors that are in the same memory-cell tier, the access lines being horizontally elongated in a horizontal x-direction and spaced relative one another in a horizontal y-direction that is perpendicular the x-direction, a capacitor electrically coupled with individual of the horizontal transistors on the capacitor side, digitlines that are individually electrically coupled with the individual horizontal transistors on the digitline side;
between immediately-adjacent of the digitlines in the x-direction, the memory-cell tiers comprising insulator material on a digitline-side edge of individual of the access lines, the insulator material tapering away from the digitline-side edge;
the insulative tiers comprising insulative material that is vertically between immediately-vertically-adjacent of the memory-cell tiers, a portion of the insulative material being laterally beyond the digitline-side edge vertically between the insulator material that is in the immediately-vertically-adjacent memory-cell tiers between the immediately-x-direction-adjacent digitlines; and
(b) being less than (a), where:
(a): minimum horizontal distance between the gate insulator of immediately-horizontally-adjacent of the horizontal transistors along the x-direction; and
(b): minimum vertical thickness of the insulator material where vertically between the portions of the insulative material of immediately-vertically adjacent of the insulative tiers.

12. The memory circuitry of claim 11 wherein the portions of the insulative material taper along the y-direction towards the capacitor.

13. The memory circuitry of claim 11 wherein the access lines between the immediately-adjacent digitlines taper along the y-direction towards the digitlines.

14. The memory circuitry of claim 11 wherein,
the portions of the insulative material taper along the y-direction towards the capacitor; and
the access lines between the immediately-adjacent digitlines taper along the y-direction towards the digitlines.

15. The memory circuitry of claim 14 wherein the tapering of each of the portions of the insulative material and the access lines taper in the same degree.

16. The memory circuitry of claim 15 wherein the degree is constant.

17. The memory circuitry of claim 11 wherein the horizontal transistor comprises a channel region that tapers towards the digitline.

18. The memory circuitry of claim 11 wherein the horizontal transistor comprises a source/drain region that tapers towards the digitline.

19. The memory circuitry of claim 11 wherein the horizontal transistor comprises two source/drain regions that taper towards the digitline.

20. The memory circuitry of claim 11 wherein the gate insulator extends laterally beyond the digitline-side edge.

21. The memory circuitry of claim 11 wherein the insulator material extends vertically along the vertically-alternating insulative tiers and memory-cell tiers between the digitlines that are immediately-adjacent one another in the x-direction.

22. Memory circuitry comprising:
vertically-alternating insulative tiers and memory-cell tiers;
memory cells in the memory-cell tiers that individually comprise a horizontal transistor having a gate, a gate insulator, a capacitor side, and a digitline side; the gate comprising part of one of a plurality of access lines that individually directly electrically couple together multiple of the gates of different ones of the horizontal transistors that are in the same memory-cell tier, the access lines being horizontally elongated in a horizontal x-direction and spaced relative one another in a horizontal y-direction that is perpendicular the x-direction, a capacitor electrically coupled with individual of the horizontal transistors on the capacitor side, digitlines that are individually electrically coupled with the individual horizontal transistors on the digitline side, the horizontal transistor comprises a channel region that tapers towards the digitline, the horizontal transistor comprises two source/drain regions that taper towards the digitline;
between immediately-adjacent of the digitlines in the x-direction, the memory-cell tiers comprising insulator material on a digitline-side edge of individual of the access lines, the insulator material tapering away from the digitline-side edge, the insulator material extending vertically along the vertically-alternating insulative tiers and memory-cell tiers between the digitlines that are immediately-adjacent one another in the x-direction, the access lines between the immediately-adjacent digitlines tapering along the y-direction towards the digitlines;
the insulative tiers comprising insulative material that is vertically between immediately-vertically-adjacent of the memory-cell tiers, a portion of the insulative material being laterally beyond the digitline-side edge vertically between the insulator material that is in the immediately-vertically-adjacent memory-cell tiers between the immediately-x-direction-adjacent digitlines, the portion tapering along the y-direction towards the capacitor; and
(b) being less than (a), where:
(a): minimum horizontal distance between the gate insulator of immediately-horizontally-adjacent of the horizontal transistors along the x-direction; and
(b): minimum vertical thickness of the insulator material where vertically between the portions of the insulative material of immediately-vertically adjacent of the insulative tiers.

23. The memory circuitry of claim 22 wherein the gate insulator extends laterally beyond the digitline-side edge.

24. The memory circuitry of claim 22 wherein part of the access lines between immediately-x-direction adjacent of the channel regions comprises an arc having a radius that is not centered on a closest corner of a closest of gate insulator.
